(19) United States
(12) Patent Application Publication
(10) Pub. No.: US 2025/0234694 A1
(43) Pub. Date: Jul. 17, 2025

(54) ELECTRONIC DEVICE

(71) Applicant: Innolux Corporation, Miaoli County (TW)

(72) Inventors: Jan-Hsiang Yang, Miaoli County (TW); Tzu-Min Yan, Miaoli County (TW)

(73) Assignee: Innolux Corporation, Miaoli County (TW)

(21) Appl. No.: 18/981,664

(22) Filed: Dec. 16, 2024

Related U.S. Application Data
(60) Provisional application No. 63/621,092, filed on Jan. 15, 2024.

(30) Foreign Application Priority Data
Sep. 19, 2024 (CN) 202411309130.3

(51) Int. Cl. H10H 29/85; H10H 29/80; H10H 29/852

(52) U.S. Cl. CPC H10H 29/857; H10H 29/8325; H10H 29/852; H10H 29/8323; H10H 29/8517

(57) ABSTRACT

An electronic device includes a first substrate, a first circuit layer, a semiconductor chip, and a transparent conductive layer. The first circuit layer is disposed on the first substrate. The semiconductor chip is disposed on the first substrate and electrically connected to the first circuit layer. The semiconductor chip includes a semiconductor die, a filling layer, and a reflective layer. The semiconductor die has a surface and another surface opposite to the surface. The filling layer surrounds the semiconductor die. The reflective layer is disposed on the filling layer and the semiconductor die. The reflective layer includes a first part and a second part. The first part is disposed on the surface of the semiconductor die. The second part is disposed on the filling layer. The conductive layer is disposed on the another surface of the semiconductor die and connects to the second part.

### CROSS-REFERENCE TO RELATED APPLICATION

This application claims the priority benefit of U.S. provisional application Ser. No. 63/621,092, filed on Jan. 15, 2024, and China application serial no. 202411309130.3, filed on Sep. 19, 2024. The entirety of each of the above-mentioned patent applications is hereby incorporated by reference herein and made a part of this specification.

### BACKGROUND

### Technical Field

The disclosure relates to an electronic device, particularly to an electronic device having a semiconductor chip that may be directly detected after transfer.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides an electronic device having a semiconductor chip that may be directly detected after transfer, to improve the transfer yield of the semiconductor chip.

According to an embodiment of the disclosure, the electronic device includes a first substrate, a first circuit layer, a semiconductor chip, and a conductive layer. The first circuit layer is disposed on the first substrate. The semiconductor chip is disposed on the first substrate and electrically connected to the first circuit layer. The semiconductor chip includes a semiconductor die, a filling layer, and a reflective layer. The semiconductor die has a surface and another surface opposite to the surface. The filling layer surrounds the semiconductor die. The reflective layer is disposed on the filling layer and the semiconductor die. The reflective layer includes a first part and a second part. The first part is disposed on the surface of the semiconductor die. The second part is disposed on the filling layer. The conductive layer is disposed on the another surface of the semiconductor die and connects to the second part.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of an electronic device in the first embodiment of the disclosure.

FIG. 2 is a cross-sectional schematic view of an electronic device in the second embodiment of the disclosure.

FIG. 3 is a cross-sectional schematic view of an electronic device in the third embodiment of the disclosure.

FIG. 4 is a cross-sectional schematic view of an electronic device in the fourth embodiment of the disclosure.

FIG. 5 is a cross-sectional schematic view of an electronic device in the fifth embodiment of the disclosure.

FIG. 6 is a cross-sectional schematic view of an electronic device in the sixth embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (α-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In the disclosure, the electronic device may include a display device, light emitting device, backlight device, virtual reality device, augmented reality (AR) device, antenna device, sensing device, tiled device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a device for sensing capacitance, light, thermal energy, or ultrasound. The tiled device may be a display tiled device or an antenna tiled device, but not limited thereto. The electronic units in the electronic device may include passive components and active components, such as capacitors, resistors, inductors, diodes, transistors, etc. The diode may include a light emitting diode (LED) or a photodiode. The light emitting diode may include, for example, an organic light emitting diode (OLED), a mini LED, a micro LED, or a quantum dot LED, but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have peripheral systems such as driving systems, control systems, light source systems, etc. to support display devices, antenna devices, wearable devices (including augmented reality or virtual reality devices, for example), vehicle-mounted devices (including car windshields, for example), or tiled devices. It should be noted that the electronic device may be any permutation and combination of the above, but not limited thereto. The following will use the electronic device to explain the content of the disclosure, but the disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

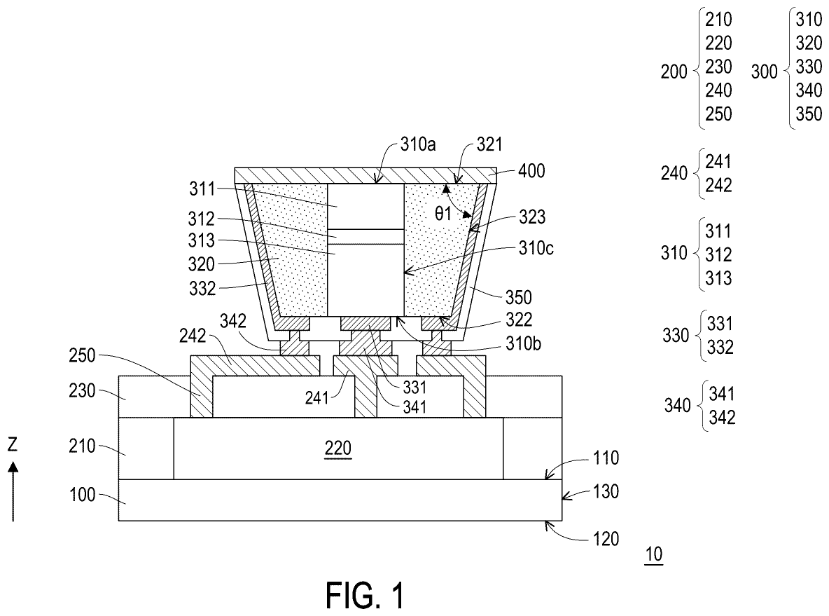

FIG. 1 is a cross-sectional schematic view of an electronic device in the first embodiment of the disclosure. Referring to FIG. 1, an electronic device 10 of the embodiment includes a first substrate 100, a first circuit layer 200, a semiconductor chip 300, and a conductive layer 400.

Specifically, the first substrate 100 includes a first surface 110, a second surface 120, and a side surface 130. The first surface 110 is opposite to the second surface 120, and the side surface 130 connects the first surface 110 and the second surface 120. In the embodiment, the first substrate 100 may include a rigid substrate, a flexible substrate, or a combination thereof. For example, the material of the first substrate 100 may include glass, quartz, sapphire, ceramic, polycarbonate (PC), polyimide (PI), polyethylene terephthalate (PET), other suitable substrate materials, or a combination thereof, but not limited thereto.

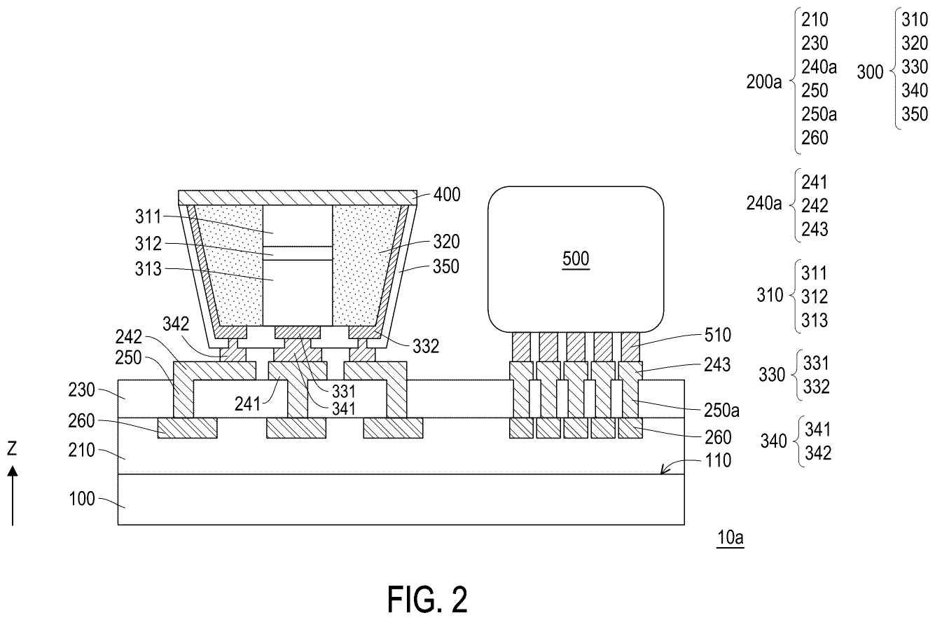

The first circuit layer 200 is disposed on the first surface 110 of the first substrate 100. The first circuit layer 200 includes an insulating layer 210, a thin-film transistor 220, an insulating layer 230, a conductive layer 240, and a via 250. The insulating layer 210 is disposed on the first surface 110. The thin-film transistor 220 is disposed in the insulating layer 210. The insulating layer 230 is disposed on the insulating layer 210. The conductive layer 240 is disposed on the insulating layer 230, and the conductive layer 240 may include a pad 241 and a pad 242. The via 250 penetrates the insulating layer 230 to connect the conductive layer 240 and the thin-film transistor 220, and the conductive layer 240 is electrically connected to the thin-film transistor 220 through the via 250. Moreover, although the first circuit layer 200 of the embodiment may be designed as an active driving circuit, but not limited thereto. In some embodiments, the first circuit layer may also be designed as a passive driving circuit (as shown in FIG. 2).

The semiconductor chip 300 is disposed on the first surface 110 of the first substrate 100. The semiconductor chip 300 is disposed on the first circuit layer 200, and the semiconductor chip 300 may be electrically connected to the thin-film transistor 220 of the first circuit layer 200. The semiconductor chip 300 includes a semiconductor die 310, a filling layer 320, a reflective layer 330, an electrode layer 340, and an insulating layer 350. Specifically, the semiconductor die 310 has a surface 310a, another surface 310b, and a side surface 310c. The surface 310a is opposite to the another surface 310b. The another surface 310b faces the first circuit layer 200, and the another surface 310b is closer to the first circuit layer 200 than the surface 310a. The side surface 310c connects the surface 310a and the another surface 310b.

In the embodiment, the semiconductor die 310 may be a vertical type chip. Specifically, in a direction Z (for example, a normal direction of the electronic device 10 or a normal direction of the first substrate 100), the semiconductor die 310 sequentially includes a first type semiconductor layer 311, an active layer 312, and a second type semiconductor layer 313 from top to bottom. The first type semiconductor layer 311 is further away from the first circuit layer 200 than the second type semiconductor layer 313, and the active layer 312 is disposed between the first type semiconductor layer 311 and the second type semiconductor layer 313.

In the embodiment, the semiconductor die 310 may be a light emitting component (for example, an organic light emitting diode, a mini light emitting diode, a micro light emitting diode, or a quantum dot light emitting diode, but not limited thereto), but not limited thereto. In the embodiment, the first type semiconductor layer 311 may be a P-type semiconductor layer, and the second type semiconductor layer 313 may be an N-type semiconductor layer, but not limited thereto. In some embodiments, the first type semiconductor layer may also be an N-type semiconductor layer, and the second type semiconductor layer may also be a P-type semiconductor layer. In the embodiment, the active layer 312 may be a light emitting layer, a photosensitive layer, or an intrinsic layer, but not limited thereto.

The filling layer 320 surrounds the semiconductor die 310. The filling layer 320 may contact the side surface 310c of the semiconductor die 310. The filling layer 320 has an upper surface 321, a lower surface 322, and a side surface 323. The upper surface 321 and the lower surface 322 are opposite to each other. The lower surface 322 faces the first circuit layer 200, and the lower surface 322 is closer to the first circuit layer 200 than the upper surface 321. The side surface 323 connects the upper surface 321 and the lower surface 322. In the embodiment, an angle θ1 between the upper surface 321 and the side surface 323 has a taper angle. The angle θ1 may be 10 degrees to 80 degrees, or 30 degrees to 70 degrees, to concentrate the light emission of the semiconductor die 310, reduce the light emission angle of the semiconductor die 310, or improve the light emission efficiency of the semiconductor die 310, but not limited thereto. In the embodiment, the material of the filling layer 320 may include acrylics, epoxies, siloxane, silica, other transparent filling materials, or a combination thereof, but not limited thereto.

The reflective layer 330 is disposed on the filling layer 320 and the semiconductor die 310. The reflective layer 330 includes a first part 331 and a second part 332. The first part 331 is disposed on the another surface 310b of the semiconductor die 310. The first part 331 may contact and be electrically connected to the second type semiconductor layer 313 of the semiconductor die 310. The second part 332 is disposed on the filling layer 320. The second part 332 is disposed on the lower surface 322 and the side surface 323 of the filling layer 320. The second part 332 is separated from the first part 331. The second part 332 may be electrically connected to the first type semiconductor layer 311 of the semiconductor die 310. In the embodiment, the material of the reflective layer 330 may include materials with high reflective characteristics, to concentrate the light emission of the semiconductor die 310, reduce the light emission angle of the semiconductor die 310, or improve the light emission efficiency of the semiconductor die 310.

The electrode layer 340 is disposed between the reflective layer 330 of the semiconductor chip 300 and the conductive layer 240 of the first circuit layer 200, and the semiconductor chip 300 is bonded and electrically connected to the first circuit layer 200 through the electrode layer 340. The electrode layer 340 may include a first electrode 341 and a second electrode 342. The first electrode 341 and the second electrode 342 are separated from each other, and both the first electrode 341 and the second electrode 342 are disposed on the same side of the semiconductor chip 300. The first electrode 341 may contact and be electrically connected to the first part 331, and the second electrode 342 may contact and be electrically connected to the second part 332. The first electrode 341 may contact and be electrically connect to the pad 241 of the conductive layer 240, and the second electrode 342 may contact and be electrically connected to the pad 242 of the conductive layer 240. In the embodiment, the material of the electrode layer 340 may include gold, tin, copper, other suitable electrode materials, or a combination thereof, but not limited thereto.

In the embodiment, the first electrode 341 may be an N-type electrode, and the second electrode 342 may be a P-type electrode, but not limited thereto. In some embodiments, the first electrode may also be a P-type electrode, and the second electrode may also be an N-type electrode. Herein, an N-type electrode refers to an electrode that is electrically connected to an N-type semiconductor layer, and a P-type electrode refers to an electrode that is electrically connected to a P-type semiconductor layer.

The insulating layer 350 surrounds the reflective layer 330, and the insulating layer 350 may separate the first part 331 and the second part 332 of the reflective layer 330. In the embodiment, the material of the insulating layer 350 may include acrylics, epoxies, siloxanes, silicon dioxide, silicon nitride, silicon oxynitride, other suitable insulating materials, or a combination thereof, but not limited thereto.

The conductive layer 400 is disposed on the surface 310a of the semiconductor die 310 and the upper surface 321 of the filling layer 320. The conductive layer 400 may connect to the second part 332 of the reflective layer 330, and the conductive layer 400 may contact and be electrically connected to the first type semiconductor layer 311 of the semiconductor die 310. The first type semiconductor layer 311 of the semiconductor die 310 is electrically connected to the second electrode 342 through the conductive layer 400 and the second part 332. In the embodiment, the material of the conductive layer 400 may include transparent conductive oxides (TCO), graphene, or metal, but not limited thereto. The material of the transparent conductive oxides may include indium tin oxide (ITO), indium zinc oxide (IZO), or indium gallium oxide (IGO), or a combination thereof, but not limited thereto. The metal may include thin metal or metal mesh, for example, a very thin metal layer (such as a magnesium layer or a silver layer) may be formed, or a metal mesh layer with light-transmitting openings may be formed by screen printing or other patterning processes. In some embodiments, the conductive layer 400 is a transparent conductive layer.

In the embodiment, since the first type semiconductor layer 311 and the second type semiconductor layer 313 of the vertical semiconductor die 310 may be electrically connected to the second electrode 342 and the first electrode 341 respectively, and the second electrode 342 and the first electrode 341 may be disposed on the same side of the semiconductor chip 300, the semiconductor chip 300 in the electronic device 10 may be directly detected or process monitored after the semiconductor chip is transferred to the first circuit layer 200, thereby improving the transfer yield. In some embodiments, a width of the semiconductor die 310 ranges from 1 to 10 μm, and a width of the semiconductor chip 300 ranges from 10 to 50 μm. In some embodiments, a projection area of the first electrode 341 and the second electrode 342 on an X-Y plane is greater than a projection area of the semiconductor die 310 on the same X-Y plane, which facilitates the subsequent bonding process of the semiconductor chip 300.

In the embodiment, since the semiconductor chip 300 may be a vertical embedded flip-chip (VEFC), the semiconductor chip 300 in the electronic device 10 may be directly detected or process monitored after the semiconductor chip is transferred to the first circuit layer 200, thereby improving the transfer yield.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

FIG. 2 is a cross-sectional schematic view of an electronic device in the second embodiment of the disclosure. Please refer to FIG. 2 and FIG. 1 simultaneously. An electronic device 10a of the embodiment is similar to the electronic device 10 in FIG. 1. The only difference between the two is that in the electronic device 10a of the embodiment, the first circuit layer 200a may be designed as a passive drive circuit, and the electronic device 10a further includes a drive chip 500.

Specifically, please refer to FIG. 2, the first circuit layer 200a includes an insulating layer 210, a conductive layer 260, an insulating layer 230, a conductive layer 240a, a via 250, and a via 250a. The insulating layer 210 is disposed on the first surface 110 of the first substrate 100. The conductive layer 260 is disposed in the insulating layer 210. The insulating layer 230 is disposed on the insulating layer 210. The conductive layer 240a is disposed on the insulating layer 230, and the conductive layer 240a may include a pad 241, a pad 242, and a pad 243. The via 250 and the via 250a penetrate the insulating layer 230 respectively. The pad 241 (or pad 242) may be electrically connected to part of the conductive layer 260 through the via 250, and the pad 243 may be electrically connected to another part of the conductive layer 260 through the via 250a.

The drive chip 500 is disposed on the first circuit layer 200a. The drive chip 500 may be bonded and electrically connected to the pad 243 of the first circuit layer 200a through a conductive component 510. The drive chip 500 may be electrically connected to the semiconductor chip 300 through the conductive component 510, the pad 243, the via 250a, the conductive layer 260, the via 250, the pad 241 (or pad 242), and the electrode layer 340. As a result, the drive chip 500 may be used to drive the semiconductor chip 300 through the first circuit layer 200a.

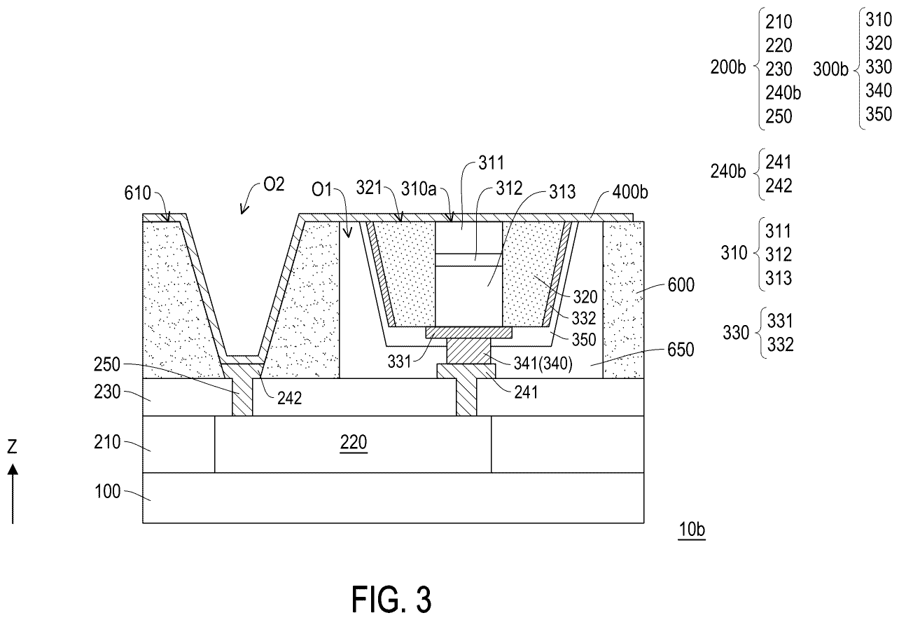

FIG. 3 is a cross-sectional schematic view of an electronic device in the third embodiment of the disclosure. Please refer to FIG. 3 and FIG. 1 simultaneously. An electronic device 10b of the embodiment is similar to the electronic device 10 in FIG. 1. The only difference between the two is that the electronic device 10b of the embodiment further includes a unit define layer 600 and an underfill 650.

Specifically, please refer to FIG. 3, the unit define layer 600 is disposed on the first circuit layer 200b. The unit define layer 600 includes a first opening O1 and a second opening O2. The first opening O1 may expose part of the insulating layer 230 and the pad 241 of the conductive layer 240b in the first circuit layer 200b, and the second opening O2 may expose the pad 242 of the conductive layer 240b. In the embodiment, the material of the unit define layer 600 may include organic photoresist, and the color of the unit define layer 600 may be transparent, black, gray, or white, but not limited thereto.

The semiconductor chip 300b is disposed in the first opening O1. The semiconductor chip 300b may be bonded and electrically connected to the pad 241 of the first circuit layer 200b through the first electrode 341 of the electrode layer 340.

The conductive layer 400b is disposed on the surface 310a of the semiconductor die 310, on the upper surface 321 of the filling layer 320, on a surface 610 of the unit define layer 600 facing away from the first circuit layer 200b, and in the second opening O2. The conductive layer 400b may be electrically connected to the pad 242 of the first circuit layer 200b through the second opening O2. As a result, the conductive layer 400b may be regarded as the second electrode, and the first type semiconductor layer 311 of the semiconductor die 310 may be electrically connected to the first circuit layer 200b through the conductive layer 400b.

The underfill 650 is disposed in a gap between the semiconductor chip 300b in the first opening O1 and the unit define layer 600 (or in a gap between the semiconductor chip 300b and the first circuit layer 200b), so that the underfill 650 may be used to fix the semiconductor chip 300b in the first opening O1. In the embodiment, the material of the underfill 650 may include acrylics, epoxides, siloxanes, silicon dioxide, other suitable adhesive materials, or a combination thereof, but not limited thereto.

In the embodiment, the semiconductor chip 300b may be a vertical embedded chip (VEC). The first type semiconductor layer 311 and the second type semiconductor layer 313 of the vertical semiconductor die 310 may be electrically connected to the conductive layer 400b and the first electrode 341 respectively, and the conductive layer 400b may be electrically connected to the pad 242 of the first circuit layer 200b through the second opening O2.

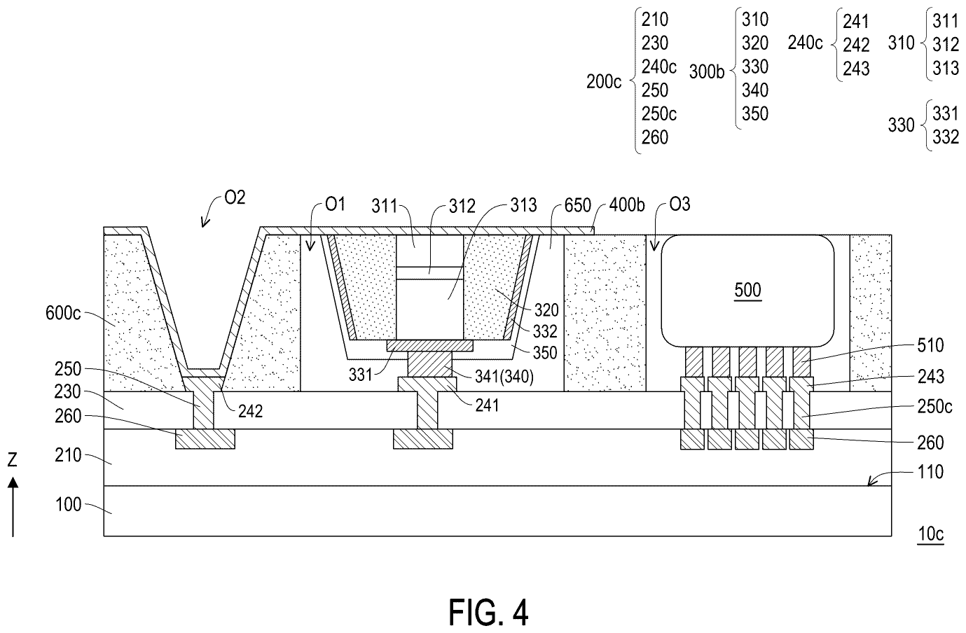

FIG. 4 is a cross-sectional schematic view of an electronic device in the fourth embodiment of the disclosure. Please refer to FIG. 4 and FIG. 3 simultaneously. An electronic device 10c of the embodiment is similar to the electronic device 10b in FIG. 3. The only difference between the two is that in the electronic device 10c of the embodiment, the first circuit layer 200c may be designed as a passive drive circuit, and the electronic device 10c further includes a drive chip 500.

Specifically, please refer to FIG. 4, the first circuit layer 200c includes an insulating layer 210, a conductive layer 260, an insulating layer 230, a conductive layer 240c, a via 250, and a via 250c. The insulating layer 210 is disposed on the first surface 110 of the first substrate 100. The conductive layer 260 is disposed in the insulating layer 210. The insulating layer 230 is disposed on the insulating layer 210. The conductive layer 240c is disposed on the insulating layer 230, and the conductive layer 240c may include a pad 241, a pad 242, and a pad 243. The via 250 and the via 250c penetrate the insulating layer 230 respectively. The pad 241 (or pad 242) may be electrically connected to part of the conductive layer 260 through the via 250, and the pad 243 may be electrically connected to another part of the conductive layer 260 through the via 250c.

The unit define layer 600c further includes a third opening O3. The third opening O3 may expose part of the insulating layer 230 and the pad 243 of the conductive layer 240c in the first circuit layer 200.

The drive chip 500 is disposed on the first circuit layer 200c and in the third opening O3. The drive chip 500 may be bonded and electrically connected to the pad 243 of the first circuit layer 200c through the conductive component 510. The drive chip 500 may be electrically connected to the semiconductor chip 300b through the conductive component 510, the pad 243, the via 250c, the conductive layer 260, the via 250, the pad 241 (or pad 242), and the electrode layer 340 (or conductive layer 400b). As a result, the drive chip 500 may be used to drive the semiconductor chip 300b through the first circuit layer 200c.

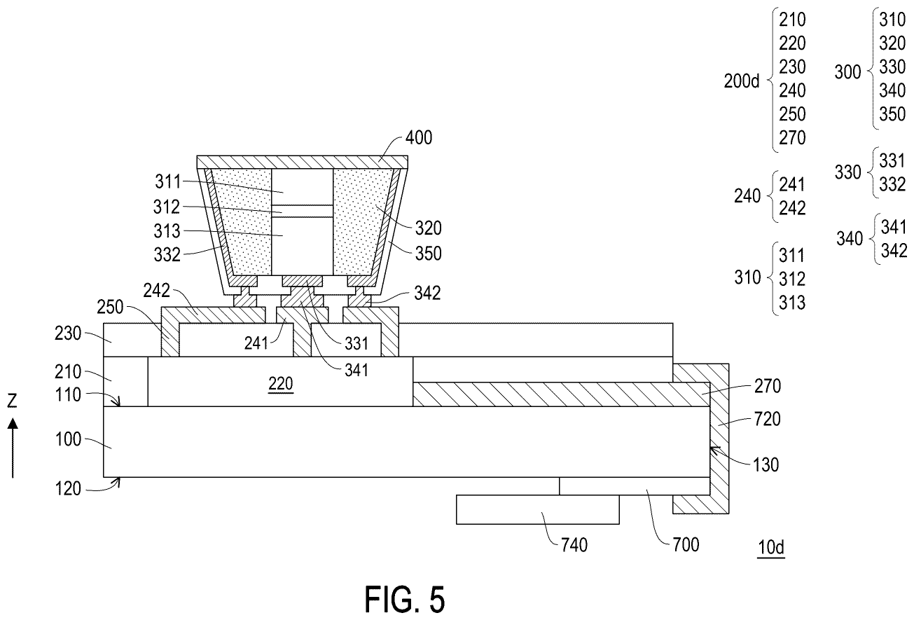

FIG. 5 is a cross-sectional schematic view of an electronic device in the fifth embodiment of the disclosure. Please refer to FIG. 5 and FIG. 1 simultaneously. An electronic device 10d of the embodiment is similar to the electronic device 10 in FIG. 1. The only difference between the two is that the electronic device 10d of the embodiment further includes a second circuit layer 700, a side circuit 720, and a circuit board 740.

Specifically, please refer to FIG. 5, the first circuit layer 200d further includes a conductive layer 270. The conductive layer 270 is disposed in the insulating layer 210, and the conductive layer 270 may be electrically connected to the thin-film transistor 220.

The second circuit layer 700 is disposed on the second surface 120 of the first substrate 100. The second circuit layer 700 includes at least a conductive layer (not shown).

The side circuit 720 is disposed on the side surface 130 of the first substrate 100. The side circuit 720 may be electrically connected to the conductive layer 270 of the first circuit layer 200d and the second circuit layer 700.

In some embodiments, the side circuit 720 and the second circuit layer 700 may be the same conductive layer, wherein the conductive layer is subsequently subjected to patterning processes to form the side circuit 720 and the second circuit layer 700 respectively.

The circuit board 740 is disposed on the second surface 120 of the first substrate 100 and the second circuit layer 700. The circuit board 740 may be electrically connected to the thin-film transistor 220 through the second circuit layer 700, the side circuit 720, and the conductive layer 270. In the embodiment, the circuit board 740 may be a flexible printed circuit (FPC) or a printed circuit board (PCB), but not limited thereto.

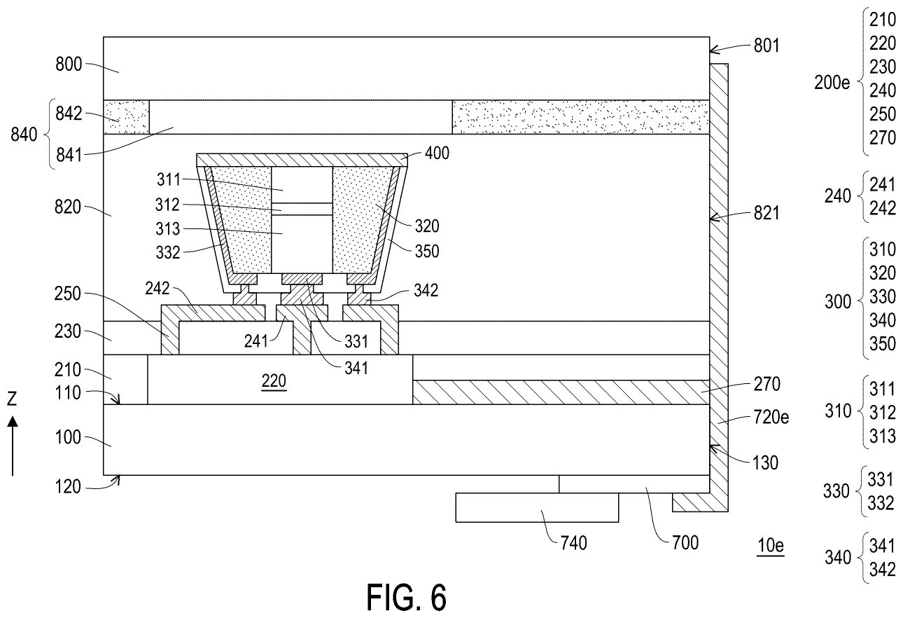

FIG. 6 is a cross-sectional schematic view of an electronic device in the sixth embodiment of the disclosure. Please refer to FIG. 6 and FIG. 5 simultaneously. An electronic device 10e of the embodiment is similar to the electronic device 10d in FIG. 5. The only difference between the two is that the electronic device 10e of the embodiment further includes a second substrate 800, an adhesive layer 820, and a light conversion unit 840.

Specifically, please refer to FIG. 6, the second substrate 800 is disposed relative to the first substrate 100. In the embodiment, the second substrate 800 may include a rigid substrate, a flexible substrate, or a combination thereof. For example, the material of the second substrate 800 may include glass, quartz, sapphire, ceramic, polycarbonate, polyimide, polyethylene terephthalate, other suitable substrate materials, or a combination thereof, but not limited thereto.

The adhesive layer 820 is disposed between the first substrate 100 and the second substrate 800. The adhesive layer 820 is disposed on the first circuit layer 200e, and the adhesive layer 820 may surround the semiconductor chip 300. In the embodiment, the material of the adhesive layer 820 may include optically clear adhesive (OCA), optical clear resin (OCR), other suitable transparent materials, or a combination thereof, but not limited thereto.

The light conversion unit 840 is disposed between the second substrate 800 and the adhesive layer 820. The light conversion unit 840 includes a light conversion layer 841 and a separation layer 842. In the Z direction, the light conversion layer 841 overlaps with the semiconductor chip 300, and the separation layer 842 does not overlap with the semiconductor chip 300. The light conversion unit 840 may include light conversion material, color filter layer, or a combination thereof.

The side circuit 720e is disposed on the side surface 130 of the first substrate 100, a side surface of the first circuit layer 200e, a side surface 821 of the adhesive layer 820, a side surface of the light conversion unit 840, and a side surface 801 of the second substrate 800. The side circuit 720e may be used to protect the side surface 821 of the adhesive layer 820.

In some embodiments, the side circuit 720e and the second circuit layer 700 may be the same conductive layer, wherein the conductive layer is subsequently subjected to patterning processes to form the side circuit 720e and the second circuit layer 700 respectively.

In summary, in the electronic device of the embodiments of the disclosure, since the first type semiconductor layer and the second type semiconductor layer of the vertical semiconductor die may be electrically connected to the second electrode and the first electrode respectively, and the second electrode and the first electrode may be disposed on the same side of the semiconductor chip, the semiconductor chip in the electronic device may be directly detected or process monitored after the semiconductor chip is transferred to the first circuit layer, thereby improving the transfer yield.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. An electronic device, comprising:
a first substrate;
a first circuit layer, disposed on the first substrate;
a semiconductor chip, disposed on the first substrate and electrically connected to the first circuit layer, and comprising:
a semiconductor die, having a surface and another surface opposite to the surface;
a filling layer, surrounding the semiconductor die; and
a reflective layer, disposed on the filling layer and the semiconductor die, and comprising:
a first part, disposed on the another surface of the semiconductor die; and
a second part, disposed on the filling layer; and
a conductive layer, disposed on the surface of the semiconductor die and connecting to the second part.

2. The electronic device according to claim 1, further comprising:
a driving chip, disposed on the first circuit layer and configured to drive the semiconductor chip.

3. The electronic device according to claim 1, wherein the first circuit layer comprises a thin-film transistor, and the semiconductor chip is electrically connected to the thin-film transistor.

4. The electronic device according to claim 1, further comprising:
a unit define layer, disposed on the first circuit layer and comprising a first opening and a second opening,
wherein the semiconductor chip is disposed in the first opening, and the conductive layer is electrically connected to the first circuit layer through the second opening.

5. The electronic device according to claim 1, wherein the first substrate comprises a first surface, a second surface and a side surface, the first surface is opposite to the second surface, the first circuit layer is disposed on the first surface, and the electronic device further comprises:
a second circuit layer, disposed on the second surface; and
a side circuit, disposed on the side surface and electrically connected to the first circuit layer and the second circuit layer.

6. The electronic device according to claim 5, further comprising:
a second substrate, opposite to the first substrate; and
an adhesive layer, disposed between the first substrate and the second substrate,
wherein the side circuit is disposed on a side surface of the second substrate and a side surface of the adhesive layer.

7. The electronic device according to claim 6, further comprising:
a light conversion layer, disposed between the second substrate and the adhesive layer, and overlapping with the semiconductor chip.

8. The electronic device according to claim 5, further comprising:
a circuit board, electrically connected to the semiconductor chip through the second circuit layer, the side circuit and the first circuit layer.

9. The electronic device according to claim 8, wherein the second circuit layer is disposed between the first substrate and the circuit board.

10. The electronic device according to claim 1, wherein the semiconductor chip further comprises:
an electrode layer, disposed between the reflective layer and the first circuit layer.

11. The electronic device according to claim 10, wherein the electrode layer comprises:
a first electrode, electrically connected to the first part; and
a second electrode, electrically connected to the second part.

12. The electronic device according to claim 11, wherein the first electrode and the second electrode are disposed on the same side of the semiconductor chip.

13. The electronic device according to claim 12, wherein the semiconductor die comprises a first type semiconductor layer, an active layer and a second type semiconductor layer, the first type semiconductor layer is electrically connected to the second electrode through the conductive layer and the second part, and the second type semiconductor layer is electrically connected to the first electrode through the first part.

14. The electronic device according to claim 1, wherein the semiconductor die comprises a first type semiconductor layer, an active layer and a second type semiconductor layer, the first type semiconductor layer is electrically connected to the conductive layer, and the second type semiconductor layer is electrically connected to the first part.

15. The electronic device according to claim 1, wherein the filling layer surrounds a side surface of the semiconductor die.

16. The electronic device according to claim 1, wherein the filling layer has an upper surface, a lower surface and a side surface, the upper surface and the lower surface are opposite to each other, the side surface connects the upper surface and the lower surface, and the second part is disposed on the side surface of the filling layer.

17. The electronic device according to claim 16, wherein an angle between the upper surface and the side surface is 10 degrees to 80 degrees.

18. The electronic device according to claim 1, wherein the first part and the second part of the reflective layer are separated from each other.

19. The electronic device according to claim 1, wherein the semiconductor chip is a vertical embedded flip-chip or a vertical embedded chip.

20. The electronic device according to claim 1, wherein the semiconductor die is a light emitting component.
